(19) United States
(12) Patent Application Publication
(10) Pub. No.: US 2026/0190883 A1
(43) Pub. Date: Jul. 2, 2026

(54) ETCHING METHOD

(71) Applicant: HITACHI HIGH-TECH CORPORATION, Minato-ku, Tokyo (JP)

(72) Inventors: Sumiko FUJISAKI, Tokyo (JP); Kazunori SHINODA, Tokyo (JP)

(21) Appl. No.: 18/845,163

(22) PCT Filed: Jul. 6, 2023
(86) PCT No.: PCT/JP2023/025171

§ 371 Date: Sep. 9, 2024

(51) Int. Cl. H10P 50/24; H10P 95/90

(52) U.S. Cl. CPC H10P 50/242; H10P 95/90

(57) ABSTRACT

An object of the present invention is to provide a technique of etching SiGe with respect to Ge with high selectivity. As one of etching methods in the present invention, the etching method for etching, as a processing object, a silicon germanium film of a film structure containing the silicon germanium film and a germanium film formed over a surface of a wafer, includes the steps of: supplying a hydrogen radical to the film structure while heating the wafer, and forming a modified layer over a surface of the film structure; and after the step of forming the modified layer, cooling the wafer to 0° C. to room temperature, supplying a gas containing sulfur hexafluoride or sulfur hexafluoride and argon to the modified layer and etching the silicon germanium film.

### TECHNICAL FIELD

The present invention relates to an etching method.

### BACKGROUND ART

Electronic apparatuses are becoming smaller and more sophisticated with miniaturization and higher integration of semiconductor devices constituting them. In a logic device, the structure of a field effect transistor (FET) has shifted from a two-dimensional planar type to a three-dimensional fin type since the 14-nm node. For further improvement in the integration degree, a GAA (Gate All Around) type FET is being developed now. The GAA type FET has a structure in which the entire periphery of the channel is surrounded with a gate and also has a structure in which many thin-film state channels called nanosheets or thin-wire state channels called nanowires are vertically stacked one after another. Although Si (silicon) is used as a material of the channels at present, a method using SiGe (silicon germanium) or Ge (germanium) having a higher mobility than Si is regarded promising in a generation of a 5 nm technology node or after.

For example, Patent Literature 1 describes a method of carrying out, for plasma etching of a structure having Si layers and SiGe layers alternately stacked one after another, selective and isotropic etching of each of the SiGe layers with respect to each of the Si layers by plasma which has been pulse-modulated with an NF₃ gas. Patent Literature 2 describes a method of supplying a substrate having, in the surface portion thereof, SiGe or Ge and Si with a processing gas containing a fluorine-containing gas and a hydrogen-containing gas and selectively etching SiGe or Ge with respect to Si. Patent Literature 3 shows a technology of subjecting a semiconductor substrate having an Si layer and an SiGe layer formed on the Si layer to plasma processing to expose the SiGe layer, followed by hydrogen plasma processing to form an Si segregation layer that protects an SiGe channel without giving a damage to the SiGe channel.

### CITATION LIST

### Patent Literature

Patent Literature 1: Japanese Unexamined Patent Application Publication No. 2015-76459
Patent Literature 2: Japanese Unexamined Patent Application Publication No. 2020-53448
Patent Literature 3: Japanese Unexamined Patent Application Publication No. 2020-170835

### SUMMARY OF INVENTION

### Technical Problem

When a Ge channel which is a channel using Ge as a material is used, its sacrificial layer is SiGe. In this case, when considering the fundamental etching properties of SiGe, SiGe is a mixed crystal semiconductor which is composed of Si, a group IV semiconductor, and Ge and in which Si atoms and Ge atoms different in size are distributed at random to form a covalent bond so that its etching properties largely depend on the composition ratio of the mixed crystal. According to the comparison in etching resistance among Si, SiGe, and Ge, Si is generally the least likely to etch and with an increase in the composition of Ge, resistance to etching decreases. This occurs because the covalent bond energy in Si—Si bond is the highest with an energy of 3.25 eV, that in Ge—Ge bond is the smallest with an energy of 2.84 eV, and that in Si—Ge bond is middle with an energy of 3.12 eV. When plasma of an ordinarily used halogen-based single gas such as CF₄, Cl₂, or HBr is used, therefore, the etching rate shows the following relationship: Si<SiGe<Ge in most cases. Therefore, a technique for achieving selective etching of SiGe with respect to Ge is difficult.

The present invention has been completed in consideration of the above-described problem and an object of it is to provide a technique of etching SiGe with respect to Ge with high selectivity.

### Solution to Problem

In order to solve the above problems, as typical one of etching methods in the present invention, an etching method for etching, as a processing object, a silicon germanium film of a film structure containing the silicon germanium film and a germanium film formed over a surface of a wafer, includes the steps of: supplying a hydrogen radical to the film structure while heating the wafer, and forming a modified layer over a surface of the film structure; and after the step of forming the modified layer, cooling the wafer to 0° C. to room temperature, supplying a gas containing sulfur hexafluoride or sulfur hexafluoride and argon to the modified layer and etching the silicon germanium film.

### Advantageous Effects of Invention

According to the present invention, it is possible to etch SiGe with respect to Ge with high selectivity.

Objects, configurations, and effects other than the above will be apparent from the description of the following embodiments.

### BRIEF DESCRIPTION OF DRAWINGS

FIG. 1 is a flow chart of an etching method according to an embodiment of the present invention.

FIG. 2 is a view showing one example of the constitution of a plasma processing device.

FIG. 3 is a view showing a time chart of an etching method.

FIG. 4 is a view showing dependence of SiGe/Ge etching selectivity on a wafer temperature during hydrogen plasma processing.

FIG. 5 is a view showing dependence of SiGe/Ge etching selectivity on hydrogen plasma processing time.

FIGS. 6A and 6B are a cross-sectional views for describing one example of a device structure to which the embodiment of the present disclosure is applied and an etched state of the device.

### DESCRIPTION OF EMBODIMENTS

Description of embodiments of the present invention will hereinafter be described referring to the drawings. In the present specification and drawings, an overlapping description on components having substantially the same function and constitution is omitted by attaching the same reference numeral to them.

To facilitate the understanding of the present invention, the position, size, shape, range, and the like of the components shown in the drawings may not be indicative of the actual position, size, shape, range and the like. The position, size, shape, range, and the like of the present invention are therefore not always limited to those disclosed in the drawings.

The term “film” means a substance formed mainly by a film formation step. For example, when a film formation step is performed on a wafer (substrate), it means a substance having a thickness smaller than that of the wafer and formed uniformly thereon. The term “film” may be replaced by a term “layer”.

### Embodiments

### (Procedure of Etching Method)

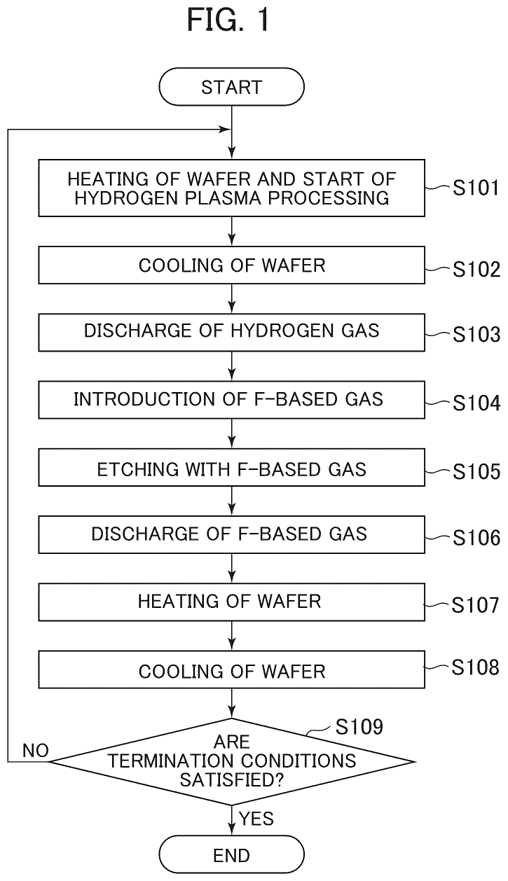

FIG. 1 is a flow chart of an etching method according to an embodiment of the present invention. Each step will hereinafter be described. The etching method disclosed herein is an etching processing method with a silicon germanium film as a processing target among film structures containing an SiGe film and a Ge film formed on the surface of a wafer.

Step S101 is a step of supplying a hydrogen radical to a film structure while heating the wafer, and thereby forming a modified layer on the surface of the film structure. Described specifically, in Step S101, a hydrogen gas is introduced into a processing chamber in which a wafer having an SiGe film and a Ge film on the surface side thereof is placed. The hydrogen gas is an H₂ gas and it may be a mixture of an H₂ gas and a dilution gas such as Ar (argon) gas. The Ar gas may be a He gas or it may be another rare gas or a nitrogen gas. The wafer temperature in the present step is adjusted to a temperature range of 100° C. or more and 350° C. or less by a stage temperature adjusting function on which the wafer is placed. In short, the wafer is heated to 150° C. to 350° C. The wafer temperature in this case may be elevated or kept by irradiating the wafer with ab electromagnetic wave by a lamp installed in the processing chamber. The hydrogen gas is activated by the plasma formed by a plasma source to separate a hydrogen radical and the resulting hydrogen radical is supplied to the film structure. A hydrogen-involved modified layer having a thickness determined by the predetermined conditions is formed.

Next steps from Step S102 to S104 are those for, after the step of forming a modified layer, cooling the wafer to 0° C. to room temperature, supplying a gas containing SF₆ or SF₆ and Ar to the modified layer, and etching the SiGe film. Described specifically, in Step S102, the wafer is speedily cooled to a temperature of 100° C. or less. The temperature of 100° C. or less may be, for example, 0° C. to room temperature. The wafer is cooled via a stage on which the wafer is placed. For speedy cooling, a rare gas such as Ar gas may be introduced at high pressure and cooling is accelerated by heat exchange. Then, the hydrogen gas is discharged speedily to complete the plasma processing (which may also be called “hydrogen plasma processing”) using a hydrogen gas (Step S103).

Next, in Step S104, a F-based gas is introduced into the processing chamber. The F-based gas is an SF₆ (sulfur hexafluoride) gas or a gas containing a SF₆ gas and argon. In addition, the F-based gas may be an inorganic gas such as SF₆ gas or NF₃ gas or a halogen-containing hydrocarbon-based compound (CF₄, CHF₃, CCl₂F₃, etc.). Similar to the hydrogen gas, the gas may be a mixed gas containing a dilution gas such as the aforesaid gas but other than Ar. Next, in Step S105, the F-based gas is activated by the plasma formed by a plasma source and due to the effect of the hydrogen-involved modified layer formed on the surface in Step S101, the SiGe film is selectively etched with respect to the Ge film. Then, the F-based gas is discharged speedily from the processing container to finish the etching processing (Step S106).

Next, Step S107 is a step of, after the etching step, heating the wafer to remove the hydrogen from the surface of the film structure. Described specifically, in Step S107, heating treatment is performed by heating the wafer to 400° C. or more as speedily as possible by a heating mechanism installed in the processing container. The heating mechanism may be such that the wafer is heated from the stage or heated by irradiating the wafer with an electromagnetic wave from a lamp such as infrared ray lamp or halogen lamp. The hydrogen gas in the modified layer which gas has remained in the SiGe film and Ge film is discharged speedily by making use of the heat.

Subsequently, the wafer is speedily cooled to a temperature of 100° C. or less (Step S108).

The step of forming a modified layer, the etching step, and the hydrogen removal step described above constitute one cycle and this cycle is repeated in multiple times. Described specifically, the steps from Step S101 to Step S108 are repeated and whether or not a desired etching amount can be achieved is determined as a termination condition (Step S109). The etching is finished at a cycle when the etching amount of the SiGe film reaches a desired one.

The order of the steps in FIG. 1 is not limited to that shown therein. For example, the order of Step S108 and Step S109 may be changed. In this case, whether or not a desired etching amount is achieved is judged after Step S107. When the etching amount is not adequate, it is possible to cool the wafer in Step S108 not to the temperature of 100° C. but to the processing temperature in Step S101. This makes it possible to carry out Step S101 speedily and shorten the time necessary for repeating the processing.

### (Constitution of Plasma Processing Device)

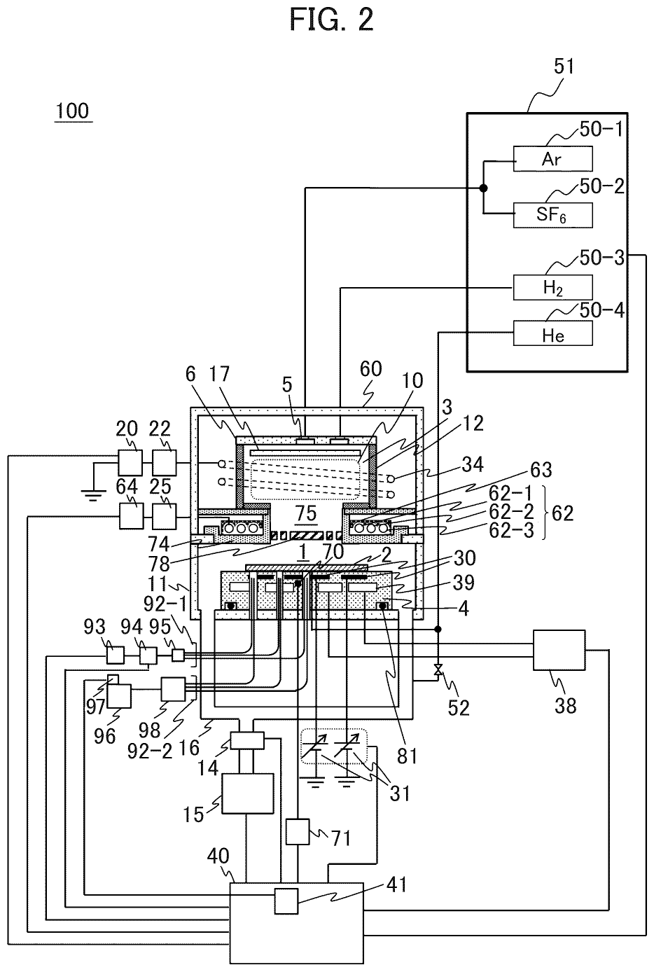

Next, one example of a plasma processing device usable for the aforesaid etching method of the present embodiment for a film structure containing an SiGe film and a Ge film will be described. FIG. 2 is a view showing one example of the constitution of a plasma processing device 100. FIG. 2 includes a cross-sectional view showing the place such as processing chamber 1 where wafer processing is carried out and a block diagram showing power sources and the like classified by function.

The processing chamber 1 is a space separated by a base chamber 11 from an external environment and configured to achieve a pressure lower than atmospheric pressure and it has therein a wafer stage 4 (which will hereinafter be called “stage 4”) on which a wafer 2, a sample to be processed, is placed. A container 60 placed above the base chamber 11 has a quartz chamber 12, an ICP coil 34, and a plasma source equipped with a high frequency power source 20. In this example, can ICP (Inductively Coupled Plasma) discharge system is used as the plasma source. The ICP coil 34 placed outside the cylindrical quartz chamber 12 is connected to the high frequency power source 20 for plasma generation via a matching device 22. As the frequency of the high frequency power, a frequency included in the frequency band of several tens of MHz, for example, 13.56 MHz is used.

The quartz chamber 12 has thereabove a top plate 6. The top plate 6 has therein a shower plate 5 and the top plate 6 has therebelow a gas dispersion plate 17. The processing gas is introduced into the processing chamber 1 from the outer periphery of the gas dispersion plate 17.

The supply flow rate of the processing gas is regulated by mass flow controllers 50-1 to 50-3 provided respectively for gases. FIG. 2 shows an example of using an H₂ gas, an SF₆ gas, and an Ar gas as the processing gas, but the kind of the gas is not limited to them.

The lower portion of the processing chamber 1 is connected to a pump 15 via a vacuum exhaust pipe 16 to reduce the pressure inside the processing chamber 1. The pump 15 is, for example, comprised of at least one of a turbomolecular pump, a mechanical booster pump, or a dry pump. In addition, the pump 15 has, upstream thereof, a pressure regulator mechanism 14 for regulating the pressure in the processing chamber 1 or in a discharge region 3 in the quartz chamber 12. The pressure regulator mechanism 14, the pump 15, and the vacuum exhaust pipe 16 will be collectively called “exhaust mechanism”. It is to be noted that the stage 4 is fixed to the base chamber 11 after an O ring 81 is provided to vacuum seal a space between the stage 4 and the base chamber 11.

The stage 4 and the quartz chamber 12 that constitutes an ICP plasma source have therebetween an IR (Infrared) lamp unit for heating the wafer 2. The IR lamp unit mainly has an IR lamp 62, a reflection plate 63 that reflects an IR light, and an IR light transmission window 74. As the IR lamp 62, a circle type (round type) lamp is used. It is to be noted that a light (electromagnetic wave) emitted from the IR lamp 62 is, for example, a light (which is called an IR light here) composed mainly of a light ranging from a visible light to a light of an infrared region. In this example, IR lamps 62-1, 62-2, and 62-3 for three rounds are installed as the IR lamp 62, but they may be for two rounds, four rounds, or the like. The IR lamp 62 has thereabove a reflection plate 63 for reflecting an IR light downward (the direction in which the wafer 2 is placed).

An IR lamp power source 64 is connected to the IR lamp 62 and they have therebetween a high frequency cut filter 25 for preventing the noise of plasma generation high frequency power that occurs at the high frequency power source 20 from flowing into the IR lamp power source 64. Further, the IR lamp power source 64 has a function of independently controlling the powers to be supplied to the IR lamps 62-1, 62-2, and 62-3, making it possible to adjust the radial-direction distribution of the heating amount of the wafer 2.

In the example shown here, the IR lamp unit has, at the center thereof, a gas flow path 75 to allow a gas supplied in the quartz chamber 12 to flow into the processing chamber 1. This gas flow path 75 has therein a slit plate (ion shielding plate) 78 with a plurality of holes for shielding ions or electrons formed in the plasma generated inside the quartz chamber 12 and allowing only a neural gas or neutral radical to pass through.

The stage 4 has therein a refrigerant flow path 39 for cooling the stage 4 and the refrigerant is circulated and supplied by a chiller 38. Further, to fix the wafer 2 to the stage 4 by electrostatic adsorption, electrostatic adsorption electrodes 30, which are plate-like electrode plates, are embedded in the stage 4 and electrostatic adsorption DC power sources 31 are connected to them, respectively.

In addition, for efficient cooling of the wafer 2, a He gas (cooling gas) can be supplied to between the back surface of the wafer 2 placed on the stage 4 and the stage 4. The supply amount of the He gas is regulated by a mass flow controller 50-4. Even when the electrostatic adsorption electrode 30 is activated and heating/cooling is performed while electrostatically adsorbing the wafer 2, the surface (surface on which the wafer is placed) of the stage 4 is coated with a resin such as polyimide to prevent the back surface of the wafer 2 from being scratched. Further, the stage 4 has therein a thermocouple 70 for measuring the temperature of the stage 4 and this thermocouple 70 is connected to a thermocouple thermometer 71.

Optical fibers 92-1 and 92-2 for measuring the temperature of the wafer 2 are installed at three positions, that is, near the center portion of the wafer 2 placed on the stage 4, near the radial-direction middle portion of the wafer 2, and near the outer periphery of the wafer 2. The optical fiber 92-1 introduces an IR light from an external IR light source 93 to the back surface of the wafer 2 to irradiate the back surface of the wafer 2 with the IR light. On the other hand, the optical fiber 92-2 collects, among IR lights irradiated by the optical fiber 92-1, an IR light that has transmitted/reflected through/by the wafer 2 and sends it to a spectroscope 96.

Described specifically, the external IR light generated at an external IR light source 93 is sent to an optical path switch 94 that turns ON/OFF an optical path. Then, the light is divided into two or more (here, divided into three) by a light distributor 95 and positions on the back surface side of the wafer 2 are irradiated with them via the three optical fibers 92-1, respectively. The IR lights absorbed/reflected by the wafer 2 are sent to the spectroscope 96 by means of the optical fibers 92-2 to obtain data of the wavelength dependence of spectrum intensity by a detector 97. The data of the wavelength dependence of spectrum intensity obtained by the detector 97 are sent to an arithmetic unit 41 of a control unit 40, where the absorption wavelength is calculated and based on the resulting absorption wavelength, the temperature of the wafer 2 can be determined. The optical fiber 92-2 has, in the middle thereof, an optical multiplexer 98, which allows switching of a light to be subjected to spectroscopic measurement to a light at each of the following measurement points, that is, the center of the wafer, the middle of the wafer, and the outer periphery of the wafer. The arithmetic unit 41 can therefore determine the temperature of each of the center of the wafer, the middle of the wafer, and the outer periphery of the wafer.

The control unit 40 controls mechanisms constituting the plasma processing device 100. Described specifically, it controls the high frequency power source 20 and controls ON/OFF of the high frequency power source 20 to the ICP coil 34. In addition, it controls the gas supply unit 51 to regulate the kind and flow rate of gases to be supplied from the individual mass flow controllers 50-1 to 50-3 into the quartz chamber 12. The control unit 40 activates the pump 15 and at the same time, controls the pressure regulator mechanism 14 to regulate a pressure inside the processing chamber 1 to a desired one (vacuum degree) while an etching gas is supplied. It may be configured with a complexed gas supplier and a mass flow controller corresponding thereto to regulate the flow rate of a complexed gas to be supplied from the mass flow controller to the quartz chamber 12.

Further, the control unit 40 controls the IR lamp power source 64 and chiller 38 so that the temperature of the wafer 2 falls within a predetermined temperature range, based on the temperature distribution data of the wafer 2 determined by the arithmetic unit 41 based on the temperature inside the stage 4 measured by the thermocouple thermometer 71 and the spectrum intensity data near the center portion of the wafer 2, near the radial-direction middle portion of the wafer, and the outer periphery of the wafer measured using the detector 97, while activating the electrostatic adsorption DC power source 31 to electrostatically adsorb the wafer 2 to the stage 4 and activating the mass flow controller 50-4 that supplies a He gas to between the wafer 2 and the stage 4.

### (Time Chart of Etching Method)

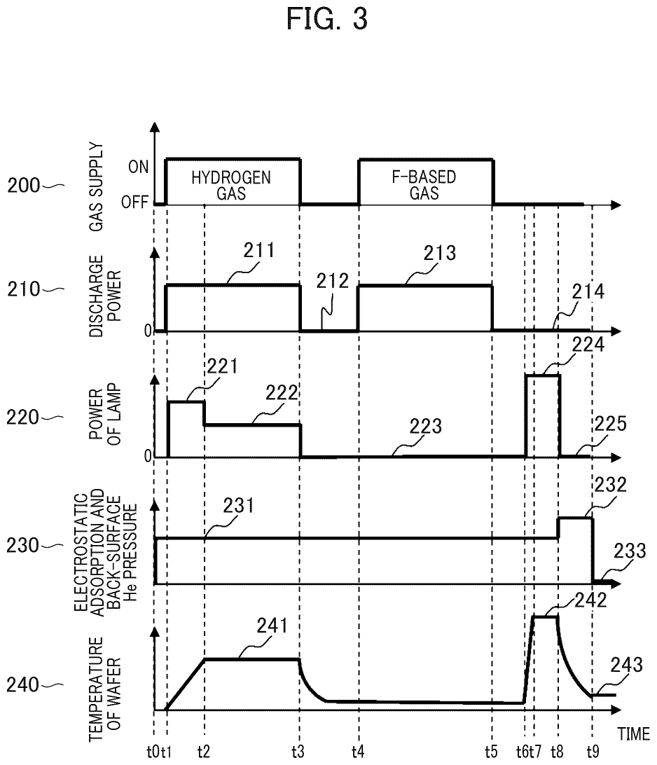

FIG. 3 shows the time chart of an etching method. Described specifically, FIG. 3 is a time chart of one etching cycle (S101 to S108) of a wafer containing in an upper layer thereof SiGe and Ge by the plasma processing device 100 according to the flow chart shown in FIG. 1. This time chart includes a “gas supply” chart 200, a “discharge power” chart 210, a “lamp power” chart 220, an “electrostatic adsorption and back-surface He pressure” chart 230, and a “wafer temperature” chart 240. These five charts are shown with an abscissa (time axis) in common. In the following description, for example, the “gas supply” chart 200 will be indicated as “chart 200”.

First, the wafer 2 containing in the upper layer thereof SiGe and Ge to be etched is carried in the processing chamber 1 via a transport port (now shown) placed in the processing chamber 1 and it is mounted on the stage 4. As shown in the chart 230, the control unit 40 activates the DC power source 31 to electrostatically adsorb the wafer 2 onto the stage 4, and thereby fix the wafer 2 onto the stage 4 (time t0). In addition, the control unit 40 controls the gas supply unit 51 to supply a wafer cooling He gas to between the back surface of the wafer 2 and the stage 4 from the mass flow controller 50-4 corresponding to an He gas and set the He gas pressure (which will also be called “back surface He pressure”) 230 between the back surface of the wafer 2 and the stage 4 at a predetermined pressure 231. When the pressure 231 is set, the DC power source 31 is activated so that the electrostatic adsorption and the back-surface He pressure are both shown on the ordinate of the chart 230 to facilitate conceptual understanding.

Subsequently, the control unit 40 regulates, as shown in the chart 200, the flow rate of a hydrogen gas supplied into the processing chamber 1 by the mass flow controller 50-3. In addition, the control unit 40 regulates the flow rate of an Ar gas supplied into the processing chamber 1 by the mass flow controller 50-1 (time t1). In addition to the regulation of the hydrogen gas and the Ar gas, the control unit 40 also regulates the opening degree of the pressure regulator mechanism 14 to set the inner pressure of the processing chamber 1 and that of the quartz chamber 12 to a target pressure. Under such a state, as shown in the chart 210, the control unit 40 starts plasma discharge in the quartz chamber 12 to generate a plasma 10 in the quartz chamber 12 by turning ON the high frequency power source 20 and thereby applying a discharge power 211, which is a high frequency power, to the discharge region 3. In addition, as shown in the chart 220, the control unit 40 turns ON the output of the IR lamp power source 64 to light the IR lamp 62 (power 221). The IR light emitted from the IR lamp 62 passes through the IR light transmission window 74 to heat the wafer 2. By heating, as shown in the chart 240, the wafer temperature increases as shown by the temperature 241. In the present embodiment, 30 seconds after the temperature increase is started (in other words, this corresponds to a time from time t2 to time t1), the wafer temperature 241 reaches 200° C. In the above example, the wafer temperature reaches 200° C. but the wafer temperature 241 may be set to fall in a range of 100° C. to 350° C.

When the wafer temperature reaches 200° C. (wafer temperature 241), the control unit 40 reduces, as shown in the chart 220, the output of the IR lamp power source 64 to the power 222 and thereby keeps the temperature of the wafer 2 at the temperature 241 for a given time. Plasma processing with a hydrogen gas is continued while keeping the temperature of the wafer 2 at 200° C. The pressure in the processing chamber 1 is set at 50 Pa and the flow rate of an Ar/H₂ gas is set at 700/200 ccm.

Under such a state, a portion of the H₂ gas is ionized and dissociated in the plasma 10. A neutral gas and radical not ionized in the region and term where the plasma 10 has been generated pass through the slit plate 78 and the wafer 2 is irradiated with them. The resulting radical enters the wafer 2 from the surface of the wafer 2 and a modified layer (which will also be called “surface modified layer”, hereinafter) with hydrogen is formed in the vicinity of the surface of the SiGe film and the Ge film. Due to the effect of the slit plate 78, the ion generated in the plasma 10 is hardly injected into the wafer 2. The formation of the surface modified layer with hydrogen therefore isotropically proceeds mainly by the hydrogen radical. The thickness of the surface modified layer formed with hydrogen increases depending on the duration time (which will also be called “plasma processing time”, hereinafter) of the plasma processing with a hydrogen gas and saturation of the thickness of the surface modified layer is detected after a time lapse of 500 seconds. The plasma processing time with an H₂ gas is therefore set at, for example, 500 seconds.

After the plasma processing time necessary for forming the surface modified layer with hydrogen has passed (time t3), the control unit 40 turns OFF the high frequency power source 20 (discharge power 212) and stops plasma discharge as shown in the chart 210. In addition, the control unit 40 turns OFF, as shown in the chart 220, the output of the IR lamp power source 64 to stop heating of the wafer 2. Further, the control unit 40 emits the gas, which has remained in the processing chamber 1, by an exhaust mechanism.

Subsequently, as shown in the chart 200, the control unit 40 regulates the flow rate of an SF₆ gas to be supplied in the processing chamber 1 by the mass flow controller 50-2 (time t4). In addition, the control unit 40 regulates the flow rate of an Ar gas to be supplied in the processing chamber 1 by the mass flow controller 50-1. Further, the control unit 40 regulates the opening degree of the pressure regulator mechanism 14 to set the pressure inside the processing chamber 1 and the pressure in the quartz chamber 12 to a target pressure. Under such a state, as shown in the chart 210, the control unit 40 turns ON the high frequency power source 20 and applies the discharge power 213 to the quartz chamber 12 to start plasma discharge therein and generate the plasma 10 in the quartz chamber 12. In such plasma processing with the SF₆ gas, the pressure in the processing chamber 1 and the quartz chamber 12 is set at 25 Pa and the flow rate of the Ar/SF₆ gas is set at 800/10 ccm.

Under such a state, a portion of the SF₆ gas is ionized and dissociated in the plasma 10. A neutral gas and radical not ionized in a region where the plasma 10 has been generated pass through the slit plate 78 and the wafer 2 is irradiated with them. This radical, mainly F radical, etches the SiGe film and the Ge film from the surface of the wafer 2. Due to the effect of the slit plate 78, the ion generated in the plasma 10 hardly enters the wafer 2. The etching with the SF₆ gas therefore isotropically proceeds mainly by the radical. Due to the effect of the modified layer with hydrogen, etching of SiGe proceeds faster than etching of Ge. The etching amount increases depending on the plasma processing time with the SF₆ gas and beginning of a decrease in the etching selectivity of SiGe with respect to Ge is detected after a lapse of a certain time. The plasma processing time with the SF₆ gas is therefore set at, for example, 20 seconds.

As shown in the chart 210, after a plasma processing time necessary for etching has passed (time t5), the control unit 40 turns OFF the high frequency power source 20 (discharge power 214) to stop plasma discharge. In addition, the control unit 40 emits the gas, which has remained in the processing chamber 1, from the exhaust mechanism.

Subsequently, as shown in the chart 220, the control unit 40 turns ON (time t6) the output of the IR lamp power source 64 to light the IR lamp 62 (power 224). The IR light emitted from the IR lamp 62 passes through the IR light transmission window 74 and heats the wafer 2. By this heating, as shown in the chart 240, the wafer temperature increases to temperature 242. Twenty seconds after the temperature increase is started, the wafer temperature 242 is detected to reach 500° C. (time t7). In the above example, the wafer temperature 242 is set to reach 500° C. but the wafer temperature 242 may be set to reach at least 400° C. or more.

It is to be noted that according to the above description, the wafer 2 is heated while being placed on the stage 4 but it may be irradiated with an IR light (electromagnetic wave) while being lifted from the stage 4 by means of a lift pin or the like to prevent thermal contact. This makes it possible to increase the wafer 2 to a desired temperature in a further short time because the conduction of heat to the stage 4 from the wafer 2 can be suppressed. In this case, the temperature of the wafer 2 may be measured using a light which has been emitted from the IR lamp 62, has passed the wafer 2, and has reached the optical fiber 92-2. In addition, the power ratio among the IR lamps 62-1, 62-3, and 62-3 may be controlled based on the in-plane radial-direction temperature distribution of the wafer 2.

Further, although the power of the lamp is kept at the power 224 as shown in the chart 220, the power 224 may be changed to keep the wafer temperature 242.

Then, as shown in the chart 220, the control unit 40 turns OFF the output of the IR lamp power source 64 (power 225, time t8) to stop heating of the wafer 2.

Subsequently, the control unit 40 controls the mass flow controller 50-1 for Ar gas supply and the mass flow controller 50-4 for He gas supply to supply an He gas to between the back surface of the wafer 2 and the stage 4 as shown in the chart 230 while supplying the processing chamber 1 with an Ar gas, and sets the pressure of the He gas between the back surface of the wafer 2 and the stage 4 to a predetermined pressure 232. As shown in the chart 240, the cooled wafer temperature 243 (time 9) has a temperature cooled to 100° C. or less and time required for cooling is 30 seconds. Then, the supply of the He gas to the back surface of the wafer is stopped and the valve 52 is opened to make the pressure of the back surface of the wafer 2 about the same as that in the processing chamber 1. The He gas is removed from the back surface of the wafer 2 to reduce the pressure of the He gas between the back surface of the wafer 2 and the stage 4 in FIG. 3 to a pressure 233. By the steps described above, the processing is completed. In the present embodiment, thus, etching by the hydrogen plasma processing and that by the plasma processing with an F-based gas both proceed isotropically.

With regards to the correspondence relation between FIG. 1 and FIG. 3, the step S101 in FIG. 1 corresponds to the processing performed between the time t0 to the time t3 in FIG. 3. The step S102 and the step S103 in FIG. 1 correspond to the processing performed between the time t3 to the time t4 in FIG. 3. The step S104 and the step S105 in FIG. 1 correspond to the processing performed between the time t4 to the time t5 in FIG. 3. The step S106 in FIG. 1 corresponds to the processing performed between the time t5 to the time t6 in FIG. 3. The step S107 in FIG. 1 corresponds to the processing performed between the time t6 to the time t8 in FIG. 3. The step S108 in FIG. 1 corresponds to the processing performed between the time t8 to the time t9 in FIG. 3. The cycle from the time t1 to the time t9 is performed in repetition until the etching amount of the SiGe film reaches a desired one.

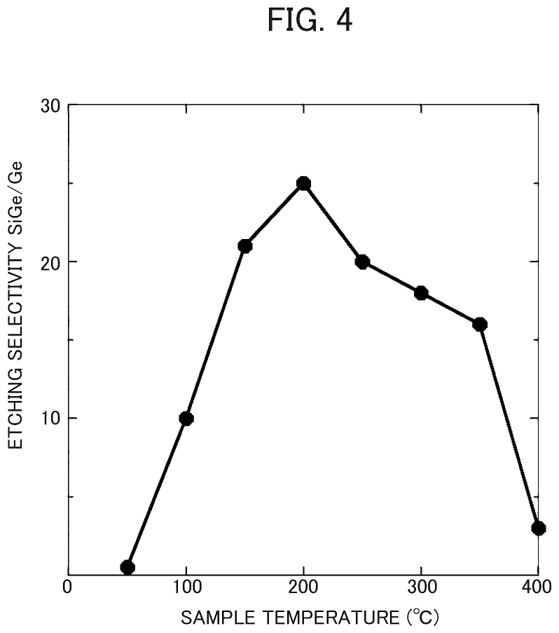

FIG. 4 shows the etching processing results of SiGe and Ge according to the process flow shown in FIG. 1 and FIG. 3. FIG. 4 shows dependence of SiGe/Ge etching selectivity on a wafer temperature during hydrogen plasma processing. This processing is performed while changing the wafer temperature in the step shown in the step S101 in FIG. 1. The wafer temperature during plasma processing with a hydrogen gas is shown on the abscissa and the etching selectivity is shown on the ordinate. The term “etching selectivity” as used herein means a ratio of the etching amount of SiGe to the etching amount of Ge. It is to be noted that the plasma processing time with a hydrogen gas is set at 500 sec. When the wafer temperature during the plasma processing with a hydrogen gas 50° C. or 400° C., the etching selectivity is below 10, while under the temperature condition of 100° C. or more and 350° C. or less, the etching selectivity is 10 or more.

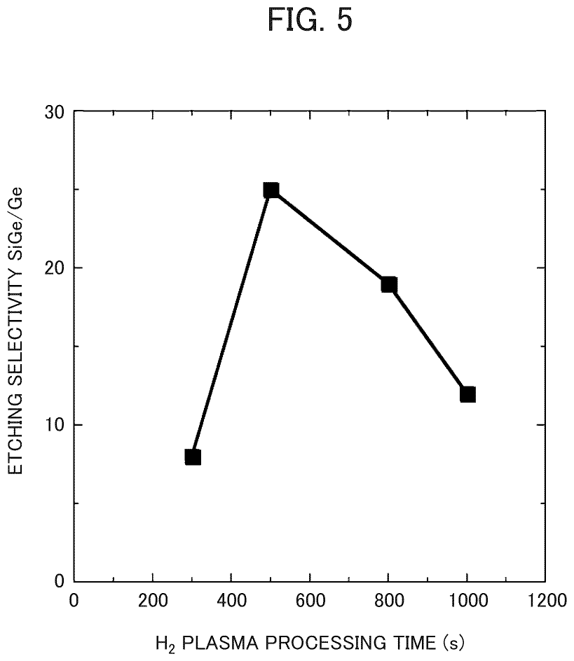

FIG. 5 shows other results of the etching processing of SiGe and Ge according to the process flow shown in FIG. 1 and FIG. 3. FIG. 5 is a view showing the dependence of SiGe/Ge etching selectivity on hydrogen plasma processing time. This processing is performed by changing the plasma processing time with a hydrogen gas in the step shown in the step S101 in FIG. 1. The plasma processing time with a hydrogen gas is shown on the abscissa and the etching selectivity is shown on the ordinate. The water temperature is fixed at 200° C. The etching selectivity is 25, the highest value, when the plasma processing time with a hydrogen gas is 500 sec and the etching selectivity decreases at a processing time shorter or longer than it.

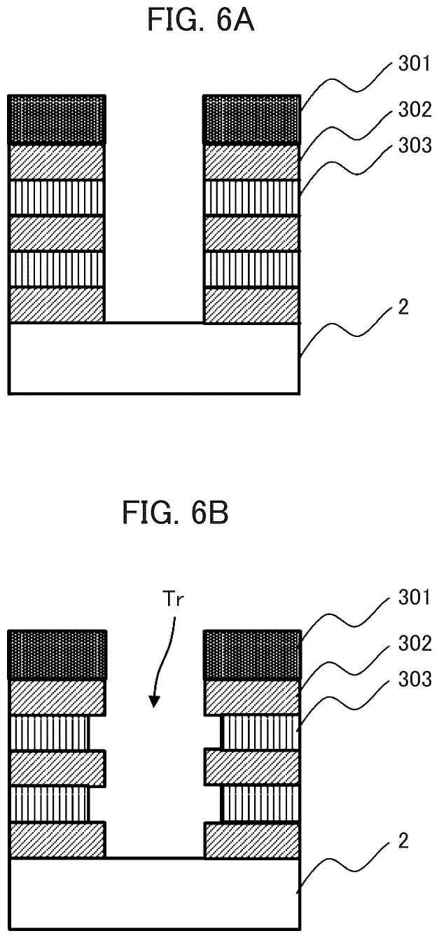

FIGS. 6A and 6B are cross-sectional views for describing one example of the structure of a device to which the embodiment of the present disclosure is applied and the device after etching. FIG. 6A shows the wafer 2 before etching and FIG. 6B shows the wafer 2 after etching. The selective etching of SiGe to Ge is applied, for example, to a device having a structure as shown in FIGS. 6A and 6B. Described specifically, as shown in FIG. 6A, before etching, a Ge film 302 and an SiGe film 303 are stacked alternately on the wafer 2 and on them, a hard mask layer 301 composed of an SiO₂ film or the like is formed. The device has a trench Tr formed in advance. The hard mask layer 301 is used as an etching mask. When the etching method of the present embodiment is given to the wafer 2, the SiGe film 303 can be etched selectively with respect to the Ge film 302. As shown in FIG. 6B, the SiGe film 303 that faces the trench Tr is etched selectively and so-called side etching of it is realized.

### Effect/Advantage

As described above, the present invention makes it possible to etch SiGe with high selectivity with respect to Ge.

The etching rate when a halogen-based single gas is used has the following relationship: Si<SiGe<Ge so that preprocessing for protecting a Ge film is necessary for the selective etching of an SiGe film. On the other hand, since the technique disclosed herein can realize a high etching selectivity (SiGe film/Ge film), efficient etching can be carried out without the processing for protecting the Ge film.

The aspects which may be the details of the present invention will be described below, but the present invention is not limited to them.

### (Aspect 1)

A method of processing a sample, includes a step of placing, in a processing chamber in a container, a substrate to be processed and having germanium and silicon germanium in which a composition ratio of germanium is larger than that of silicon, processing the sample by supplying it with an H₂ gas-containing processing gas under an excited state while keeping the sample at a temperature of 100° C. or more and 350° C. or less, and then selectively etching the silicon germanium with respect to the germanium, each of the sample, with an F-containing processing gas.

### (Aspect 2)

In the processing method of a sample as described in Aspect 1, the F-containing processing gas contains any of SF₆, CF₄, and NF₃.

### (Aspect 3)

In the method of processing a sample as described in either Aspect 1 or Aspect 2, the etching processing step with the F-containing processing gas is performed while setting the temperature of the sample at 100° C. or less.

### (Aspect 4)

The method of processing a sample as described in any of Aspects 1 to 3, further includes, after the etching processing step, a step of heating the sample to 400° C. or more with an electromagnetic wave irradiated from an infrared lamp or halogen lamp placed in the processing chamber.

### (Aspect 5)

In the method of processing a sample as described in any of Aspects 1 to 4, the F-containing gas contains SF₆.

### (Aspect 6)

In the method of processing a sample as described in any of Aspects 1 to 5, the processing gas containing an H₂ gas in an excited state contains a hydrogen radical.

### (Aspect 7)

In the method of processing a sample as described in any of Aspects 1 to 6, in the processing step of the sample, the temperature of the sample is adjusted by placing the sample on an upper surface of a refrigerant flow path which is placed in a lower portion in the processing chamber and through which a refrigerant having a predetermined temperature flows.

### REFERENCE SIGNS LIST

1: Processing chamber, 2: wafer, 3: discharge region, 4: wafer stage, 5: shower plate, 6: top plate, 10: plasma, 11: base chamber, 12: quartz chamber, 14: pressure regulator mechanism, 15: pump, 16: vacuum exhaust pipe, 17: gas dispersion plate, 20: high frequency power source, 22: matching device, 25: high frequency cut filter, 30: electrostatic adsorption electrode; 31: electrostatic adsorption DC power source, 24: ICP coil, 38: chiller, 40: control unit, 41: arithmetic unit, 45: tank, 46: heater, 47: complexed gas supplier, 50: mass flow controller, 51: gas supply unit, 52, 53, 54: valve, 60: container, 62: IR lamp, 63: reflection plate, 64: IR lamp power source, 70: thermocouple, 71: thermocouple thermometer, 74: IR light transmission window, 75: gas flow path, 78: slit plate, 81: O ring, 92: optical fiber, 93: external IR light source, 94: optical path switch, 95: light distributer, 96: spectroscope, 97: detector, 98: light multiplexer, 100: plasma processing device, 301: hard mask layer, 302: Ge film, and 303: SiGe film.

1. An etching method for etching, as a processing object, a silicon germanium film of a film structure containing the silicon germanium film and a germanium film formed over a surface of a wafer, the etching method comprising the steps of:
supplying a hydrogen radical to the film structure while heating the wafer, and forming a modified layer over a surface of the film structure; and
after the step of forming the modified layer, cooling the wafer to 0° C. to room temperature, supplying a gas containing sulfur hexafluoride or sulfur hexafluoride and argon to the modified layer and etching the silicon germanium film.

2. The etching method according to claim 1, further comprising, after the etching step, a step of heating the wafer to remove hydrogen from the surface of the film structure.

3. The etching method according to claim 2, wherein
in the hydrogen removing step, the wafer is heated by irradiation of an electromagnetic wave from a lamp.

4. The etching method according to claim 1, wherein
in the step of forming a modified layer, the wafer is heated to 150° C. to 350° C.

5. The etching method according to claim 2, wherein
the step of forming a modified layer, the step of etching, and the step of removing hydrogen constitute one cycle and this cycle is repeated in a plurality of times.

6. The etching method according to claim 2, wherein
in the step of forming a modified layer, the wafer is heated to 150° C. to 350° C.

7. The etching method according to claim 3, wherein
in the step of forming a modified layer, the wafer is heated to 150° C. to 350° C.

8. The etching method according to claim 1, further comprising:
after the etching in the step of forming the modified layer and etching, a step of heating the wafer to remove hydrogen from the surface of the film structure constitute one cycle; and
repeating the cycle a plurality of times.
